(19) United States
(12) Patent Application Publication
(10) Pub. No.: US 2019/0131164 A1
(43) Pub. Date: May 2, 2019

(54) SUBSTRATE PROCESSING APPARATUS

(71) Applicant: SAMSUNG ELECTRONICS CO., LTD., Suwon-si (KR)

(72) Inventors: Byeong Sang KIM, Hwaseong-si (KR); Ki Ju SOHN, Gunpo-si (KR); Ju Hyun LEE, Suwon-s (KR); Dong Wook KIM, Seoul (KR); Kyung Bin PARK, Seoul (KR); Woo Sub SHIM, Hwaseong-si (KR); Jung Wook KIM, Seongnam-si (KR); Ho YU, Pohang-si (KR); Myoung Soo CHOI, Hwaseong-si (KR); Eun Soo HWANG, Seoul (KR)

(21) Appl. No.: 15/996,848

(22) Filed: Jun. 4, 2018

(30) Foreign Application Priority Data
Oct. 27, 2017 (KR) 10-2017-0141299

(51) Int. Cl. H01L 21/687; H01J 37/32; H01L 21/67

(52) U.S. Cl. CPC H01L 21/68735; H01L 21/67017; H01J 37/32834; H01J 37/3244

(57) ABSTRACT

A substrate processing apparatus includes an exhaust unit including a lower surface in which an outlet is formed and four side walls extended from the lower surface, the exhaust unit having exhaust wings protruding from two opposing side walls, a shower head located in the exhaust unit and having distribution holes, and an adjuster disposed on each of side walls of the exhaust unit between the exhaust wings.

### CROSS-REFERENCE TO RELATED APPLICATION

Korean Patent Application No. 10-2017-0141299 filed on Oct. 27, 2017 in the Korean Intellectual Property Office, and entitled: “Substrate Processing Apparatus,” is incorporated by reference herein in its entirety.

### BACKGROUND

### 1. Field

Embodiments relate to a substrate processing apparatus.

### 2. Description of the Related Art

In semiconductor and display manufacturing processes, various methods for surface cleaning and the surface modification of substrates have been researched. In detail, semiconductor wafers and display devices have become larger, so cases in which large substrates are handled have increased.

### SUMMARY

Embodiments are directed to a substrate processing apparatus, including an exhaust unit including a lower surface in which an outlet is formed and four side walls extended from the lower surface, the exhaust unit having exhaust wings protruding from two opposing side walls, a shower head located in the exhaust unit and having distribution holes, and an adjuster disposed on each of side walls of the exhaust unit between the exhaust wings.

Embodiments are also directed to a substrate processing apparatus, including an exhaust unit including an exhaust path discharging a process material, and having exhaust wings protruding from two opposing side walls, a shower head located in the exhaust unit and having distribution holes, and having an upper surface that is curved, and an adjuster disposed on each of side walls of the exhaust unit between the exhaust wings.

Embodiments are also directed to a substrate processing apparatus, including an exhaust unit including an exhaust path discharging a process material, and having exhaust wings extended from two opposing side walls and accommodating a substrate therebetween, and a shower head located in the exhaust unit and having distribution holes.

### BRIEF DESCRIPTION OF THE DRAWINGS

Features will become apparent to those of skill in the art by describing in detail example embodiments with reference to the attached drawings in which:

FIGS. 1A and 1B illustrate a schematic front view and a schematic side view of a substrate processing apparatus according to an example embodiment;

FIG. 2 illustrates a schematic plan view of a substrate processed using a substrate processing apparatus according to an example embodiment;

FIG. 3 illustrates a schematic exploded perspective view of a substrate processing apparatus according to an example embodiment;

FIG. 4 illustrates a schematic perspective view of a substrate processing apparatus according to an example embodiment;

FIGS. 5A through 5C illustrate enlarged views of an adjuster of a substrate processing apparatus according to an example embodiment;

FIGS. 6 through 9 illustrate views of a substrate processing method using a substrate processing apparatus according to an example embodiment;

FIGS. 10 through 13 illustrate schematic front views of a substrate processing apparatus according to an example embodiment;

FIGS. 14A through 15B illustrate schematic front views and side views of a substrate processing apparatus according to an example embodiment; and

FIGS. 16A through 17B illustrate views of a simulation result of a process gas concentration of a substrate processing apparatus according to an example embodiment.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey example implementations to those skilled in the art. In the drawing figures, the dimensions of layers and regions may be exaggerated for clarity of illustration. Like reference numerals refer to like elements throughout.

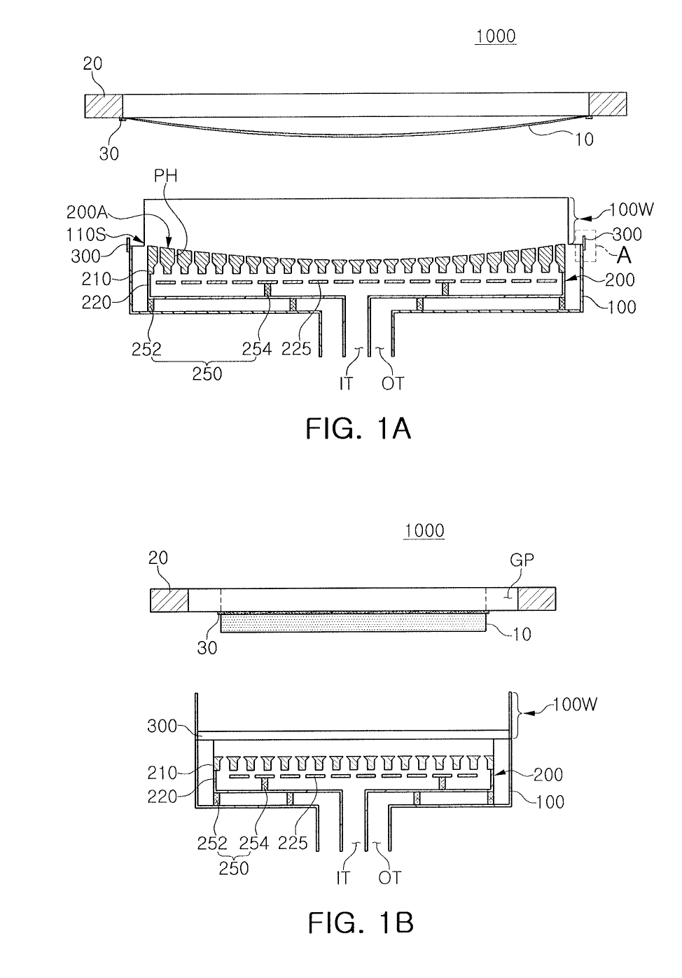

FIGS. 1A and 1B are a schematic front view and a schematic side view of a substrate processing apparatus according to an example embodiment.

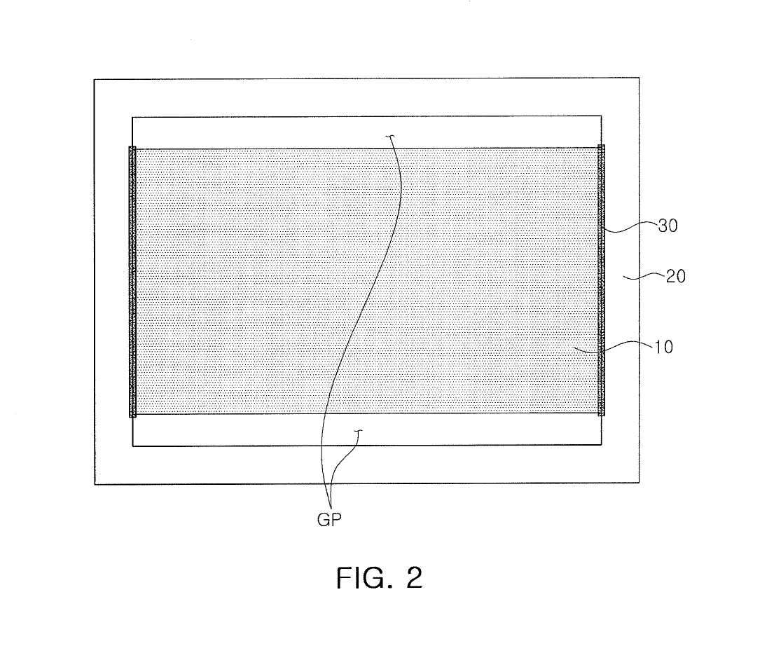

FIG. 2 is a schematic plan view of a substrate processed using a substrate processing apparatus according to an example embodiment.

A substrate processing apparatus according to an example embodiment may allow a surface of a substrate to be treated without a separate process chamber, for example by using the substrate itself as a side of a processing cavity. Thus, a deposition or processing operation may be performed without the substrate being located in a process chamber. Thus, a configuration of the apparatus may be simplified and miniaturized, and an operation may be effectively performed.

Referring to FIGS. 1A and 1B, a substrate processing apparatus 1000 may include an exhaust unit 100, a shower head 200 disposed in the exhaust unit 100, and an adjuster 300 disposed on each of two side walls of the exhaust unit 100. The substrate processing apparatus 1000 may further include supporting members 250 disposed in the shower head 200 and the exhaust unit 100.

A substrate 10 (a surface of which is to be treated by the substrate processing apparatus 1000) may be provided to be fixed by a substrate frame 20. As illustrated in FIGS. 1 and 2, opposite ends of the substrate 10 may be fixed to the substrate frame 20 by a fixing part 30. As shown in FIG. 2, opposite ends that are not fixed by the fixing part 30 may be spaced apart from the substrate frame 20, and a gap GP may be formed between each of the both ends and the substrate frame 20.

As shown in FIG. 1A, the substrate 10 may be a flexible substrate. Sagging may occur in a region of the substrate that is spaced apart from the fixing part 30. For example, sagging may occur between opposite ends of the substrate 10 that are fixed by the fixing part 30. Thus, while mounted to the substrate frame 20, the substrate 10 may be curved, and may have a have a curved surface concave toward the substrate processing apparatus 1000.

The substrate frame 20 may be provided for an easy treatment in a process when the substrate 10 is a substrate of, for example, 50 inches or more, for example, a large substrate of 100 inches or more.

The fixing part 30 may be a component such as a clamp, etc. In an example embodiment, the fixing part 30 may have, for example, a form of an insertion groove. The substrate 10 may or may not be fixed to the substrate frame 20, and may be provided in various ways. In an example embodiment, the substrate 10 may be provided as, for example, an air floating unit. In another example embodiment, the substrate 10 may be provided using a roll-to-roll processing method, and the substrate processing apparatus 1000 may be applied thereto.

The exhaust unit 100 may include a lower surface in which an outlet OT is formed, and four side walls extended upwards from an edge of the lower surface. The exhaust unit 100 may be formed of, for example, stainless steel.

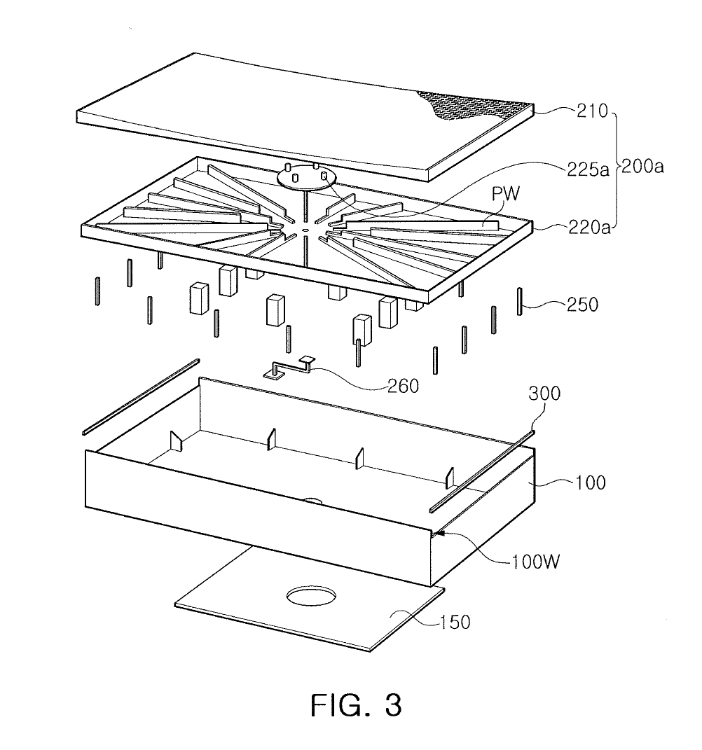

Among the side walls, two opposing side walls, illustrated in the side view of FIG. 1B and the perspective view of FIG. 3, may have exhaust wings 100W protruding upwardly. The exhaust wings 100W may be a region in which the side walls are extended upwards to be elongated. In another implementation, the exhaust wings 100W may be provided as separate members, connected to the side walls, to protrude.

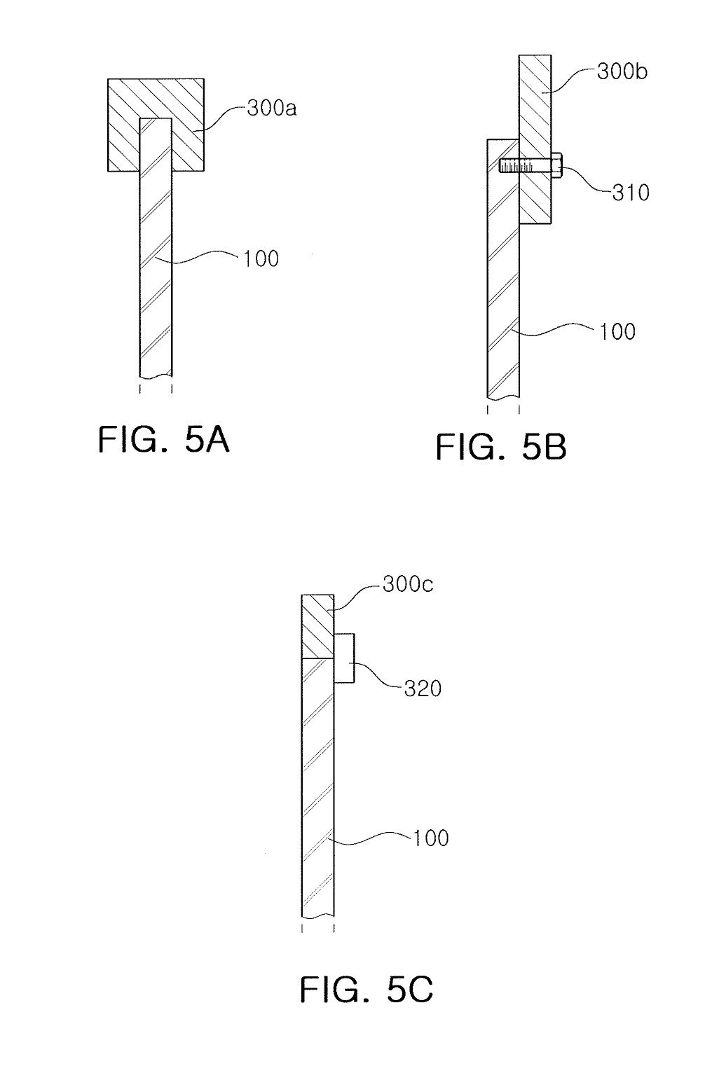

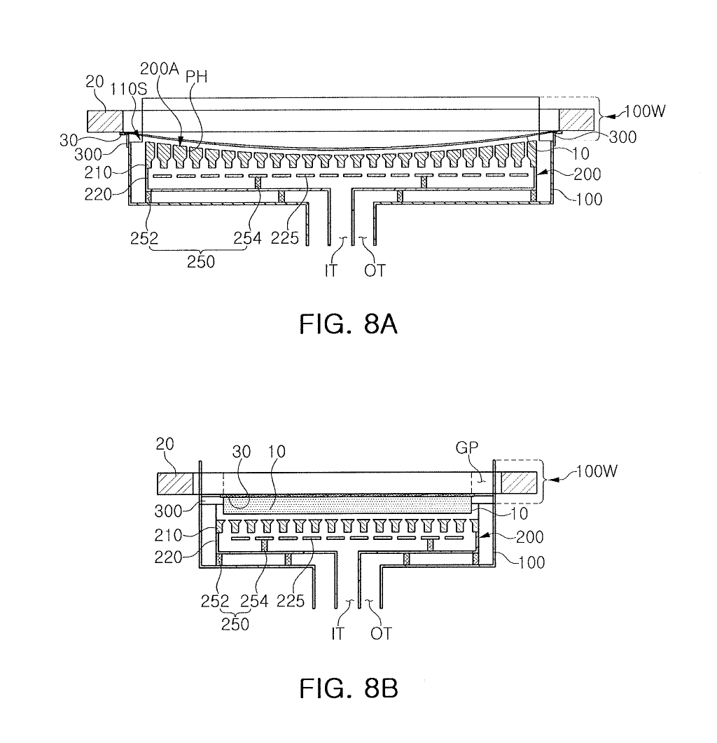

The exhaust wings 100W may be provided to be inserted into the gap GP between the substrate frame 20 and the substrate 10, when the substrate 10 is processed, as discussed in further detail below in connection with, for example, FIG. 8B. Thus, a process gas used when the substrate 10 is processed and byproducts thereof may be prevented from flowing out toward the gap GP. Thus, the substrate processing apparatus 1000 may perform treatment of the substrate 10 without a separate process chamber accommodating the substrate 10, which will be described in more detail with reference to FIGS. 5 through 8.

Side walls of the exhaust unit 100 on which the exhaust wings 100W are formed may have bent portions 1105 on both sides, as illustrated in FIG. 1A. Widths of the exhaust wings 100W may be formed to be relatively narrow in the side walls by means of the bent portions 110S. The bent portions 110S may be adjusted according to a size of the substrate frame 20, an arrangement of the adjuster 300, a process region of the substrate 10, and the like, or the bent portions 110S may be omitted.

As shown in FIG. 1A, the shower head 200 may be disposed in the exhaust unit 100, and may include an upper plate 210, a lower plate 220, and a diffusion plate 225. The shower head 200 may be formed of a metal, for example, stainless steel. The shower head 200 may be provided to distribute a process material flowing from an inlet IT in a lower portion, to eject the process material upwardly, and to provide the process material to a surface, for example, an upper surface, of the substrate 10.

The shower head 200 may have an upper surface 200A that is a curved surface. The upper surface 200A may have a curved surface corresponding to a curved surface of the substrate 10. For example, the upper surface 200A may have a curved surface that is the same as or similar to the curved surface of the substrate 10. For example, the form of the shower head 200 may be such that, even when sagging occurs in the substrate 10, a uniform space may be provided between the substrate 10 and the shower head 200, so the substrate 10 may be uniformly processed.

The upper plate 210 may be formed of through tubes, and may include distribution holes PH in which a process gas or the like may flow. The distribution holes PH may be defined by the through tubes forming the upper plate 210. The lower plate 220 may be disposed below the upper plate 210, and may include the diffusion plate 225 therein. The inlet IT may be formed in a lower surface of the lower plate 220, and a process material flowing therefrom (for example, a process gas) may be dispersed by the diffusion plate 225 and may be provided toward an upper portion of the lower plate 220 through the distribution holes PH.

The supporting members 250 may include lower supporting members 252 disposed below the shower head 200 and upper supporting members 254 disposed in the shower head 200. The lower supporting members 252 may be disposed between a lower surface of the exhaust unit 100 and the shower head 200. The upper supporting members 254 may be disposed between a lower surface of the shower head 200 and the diffusion plate 225. The arrangement and form of the supporting members 250 may be suitably varied.

The adjuster 300 may adjust a distance between the substrate 10 or the substrate frame 20 and the substrate processing apparatus 1000. The adjuster 300 may be disposed on opposing ones of the side walls that do not having the exhaust wings 100W. The adjuster 300 may be disposed along the side walls to be extended in one direction. The adjuster 300 may be fixed to the side walls, and may be provided to allow a length thereof to be varied or may be provided to be replaced. The adjuster 300 may be located to be in contact with or to be adjacent to the substrate 10 or the substrate frame 20 when the substrate 10 is processed. When the adjuster 300 is located in contact with the substrate 10 or the substrate frame 20, a process gas may be more effectively prevented from flowing out.

The adjuster 300 may be formed of a durable material for a process material. The adjuster 300 may include at least one among, for example, glass, quartz, polyethylene terephthalate (PET), polytetrafluoroethylene (PTFE), polydimethylsiloxane (PDMS), polycarbonate (PC), Teflon, and polyethylene (PE).

FIG. 3 is a schematic exploded perspective view of a substrate processing apparatus according to an example embodiment.

Referring to FIG. 3, the exhaust unit 100, a shower head 200a, and the adjuster 300 of a substrate processing apparatus are illustrated. Supporting members 250, a gas supply pipe 260, and a fixing portion 150 are illustrated together.

The exhaust unit 100 may be fixed to components, such as a driving portion below the exhaust unit 100, or the like, by the fixing portion 150. The exhaust unit 100 may have the exhaust wings 100W on opposing side walls. The adjuster 300 may be disposed on side walls that do not have the exhaust wings 100W.

The gas supply pipe 260 may be disposed below the shower head 200a. The supporting members 250 may be disposed between the shower head 200a and the exhaust unit 100. As illustrated in an example embodiment, the supporting members 250 may be provided while a portion of the supporting members is fixed to a lower end of the exhaust unit 100.

The shower head 200a may include, for example, the upper plate 210, a diffusion plate 225a, and a lower plate 220a. The upper plate 210 may have distribution holes, and the lower plate 220a may support the upper plate 210 and the diffusion plate 225a. In an example embodiment of FIG. 3, the diffusion plate 225a may be only disposed in the center, in a different manner from an example embodiment of FIGS. 1A and 1B. In this case, partition walls PW, formed in the lower plate 220a, may act to diffuse a process material. The shower head 200a may have an upper surface that is a curved surface, and the curved surface may be downwardly convex.

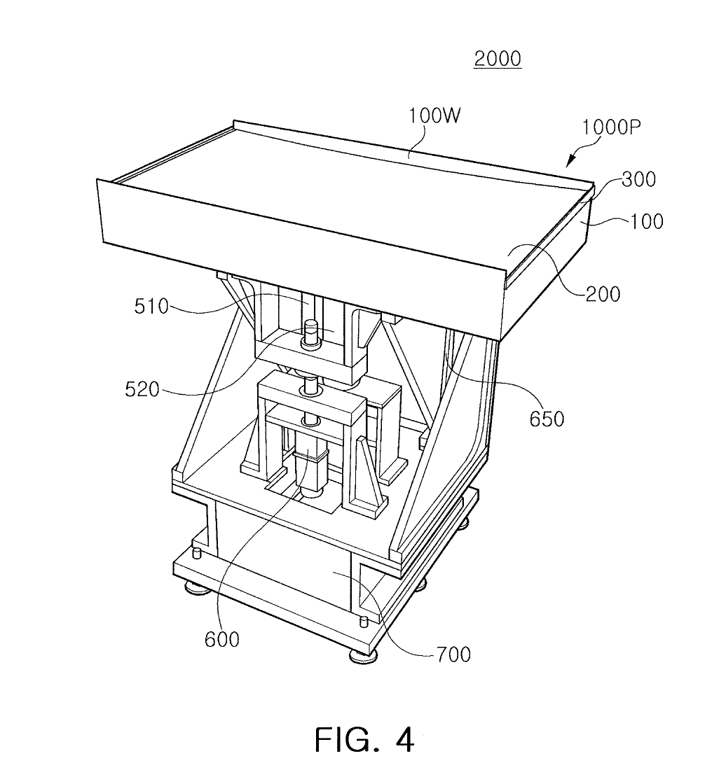

FIG. 4 is a schematic perspective view of a substrate processing apparatus according to an example embodiment.

Referring to FIG. 4, a substrate processing apparatus 2000 may include a supply bellows 510, an exhaust bellows 520, a vertical driving portion 600, an LM guide (linear motion guide) 650, and a support portion 700, disposed in a lower portion of the substrate processing apparatus, in addition to a substrate processing portion 1000P including the exhaust unit 100, the shower head 200, and the adjuster 300.

One end of each of the supply bellows 510 and the exhaust bellows 520 may be connected to the inlet IT and the outlet OT, described above with reference to FIGS. 1A and 1B, respectively. The other end of the supply bellows 510 may be connected to a gas supply unit, and the other end of the exhaust bellows 520 may be connected to an air blower.

The vertical driving portion 600 may allow the substrate processing portion 1000P to be vertically lifted in order to process a substrate, and the substrate processing portion 1000P may move vertically along the LM guide 650. The support portion 700 may be provided to support the components of the substrate processing apparatus 2000 in a lower portion and a side surface of the components.

FIGS. 5A through SC are enlarged views illustrating an adjuster of a substrate processing apparatus according to an example embodiment. FIGS. 5A through SC are enlarged view of regions corresponding to portion A of FIG. 1A.

Referring to FIG. 5A, an adjuster 300a may be disposed to be fastened in the form of a rectangular C or U to an upper end of a side wall of the exhaust unit 100. The adjuster 300a may be coupled to the exhaust unit 100 while the adjuster 300a is bonded to the exhaust unit 100 or simply inserted into the exhaust unit 100. The adjuster 300a may be selected and replaced in accordance with a desired height among a plurality of adjusters 300a having different heights to be coupled to the exhaust unit 100.

Referring to FIG. 5B, an adjuster 300b may be disposed to be fastened to an outer side surface of a side wall of the exhaust unit 100 by a fastening portion 310. The fastening portion 310 may be, for example, a fixing member such as a bolt. The adjuster 300b may have a plurality of grooves into which the fastening portion 310 is able to be inserted, and may be fastened to a groove by selecting the groove so as to protrude from an upper end of a side wall of the exhaust unit 100 as much as a desired length.

Referring to FIG. 5C, an adjuster 300c may be disposed on an upper surface of a side wall of the exhaust unit 100, and may be coupled to the side wall by a coupling portion 320. The coupling portion 320 may be, for example, a member including an adhesive.

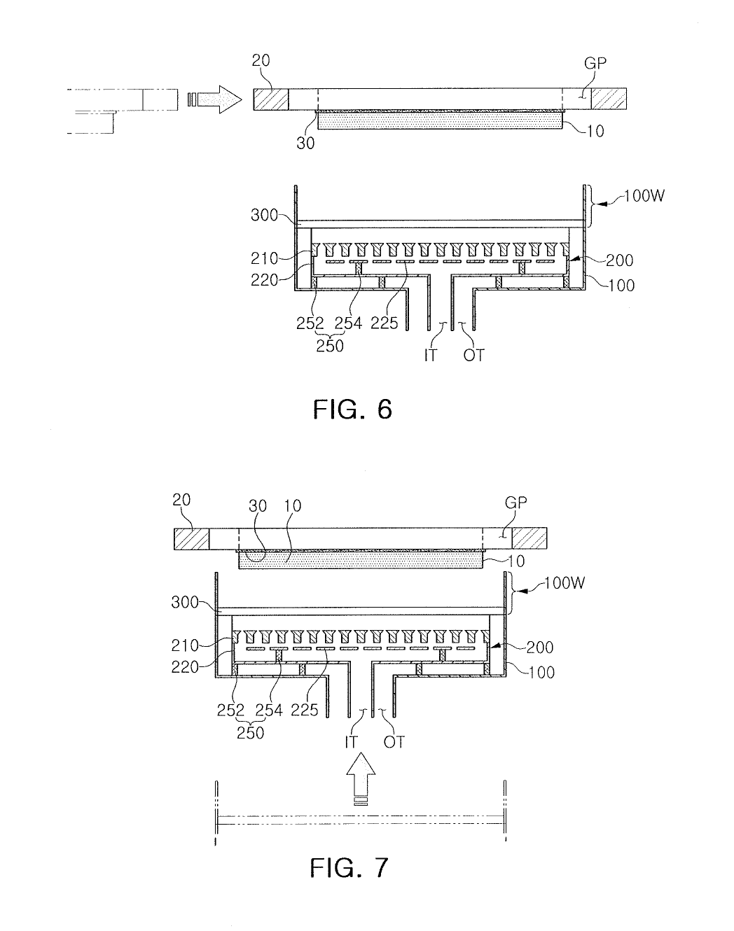

FIGS. 6 through 9 are views illustrating a substrate processing method using a substrate processing apparatus according to an example embodiment.

Referring to FIG. 6, the substrate 10, mounted on the substrate frame 20, may be transferred to the substrate processing apparatus 1000 by a transfer device. The substrate 10 and the substrate frame 20 may be transferred by a separate transfer apparatus.

Referring to FIG. 7, the substrate processing apparatus 1000 may be lifted by a driving portion below the substrate processing apparatus 1000 to allow the exhaust unit 100, the shower head 200, and the adjuster 300 to oppose the substrate 10. For example, the substrate processing apparatus 1000 may be moved vertically by a driving portion, such as the vertical driving portion 600 of FIG. 4.

Referring to FIGS. 8A and 8B, the substrate processing apparatus 1000, lifted so as to perform a processing operation on the substrate 10, is illustrated. Some components, including the exhaust unit 100 and the shower head 200 of the substrate processing apparatus 1000, may be lifted toward the substrate 10 to a minimum distance between the substrate 10 and the shower head 200 previously specified by a user, and then may be stopped.

As shown in FIG. 8B, the exhaust wings 100W of the exhaust unit 100 may be inserted into the gap GP between the substrate 10 and the substrate frame 20. As shown in FIG. 8A, on each of side walls of the exhaust unit 100 not having the exhaust wings 100W, the adjuster 300 on each of the side walls may be located to be close to or to be in contact with the substrate 10 or the substrate frame 20. A minimum distance (for example, a distance between the substrate 10 and the shower head 200 controlled by the adjuster 300) may be determined in consideration of a size of the substrate 10, a type of material used when the substrate 10 is processed, an injection speed, and the like. The substrate 10 may be accommodated in a region surrounded by side walls of the exhaust unit 100 and the adjuster 300 to be processed. Thus, a substrate processing apparatus according to an example embodiment may perform treatment of the substrate 10 without a separate process chamber sealing the substrate 10.

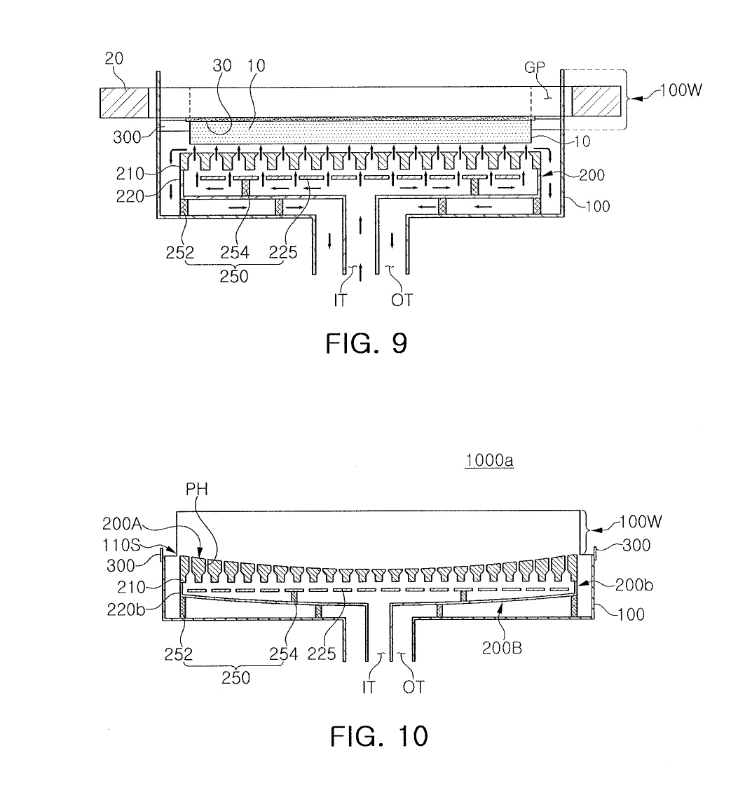

Referring to FIG. 9, a material for processing the substrate 10, for example, a gaseous substance, may be supplied through the inlet IT from a separate supply portion to be provided to an upper portion of the shower head 200, as indicated by the arrows. After the gaseous substance is first diffused through the diffusion plate 225, the gaseous substance may pass through the distribution holes PH and may be dispersed to a surface of the substrate 10. The gaseous substance used for processing the substrate 10, and byproducts generated during the processing, may move along an edge of the shower head 200 and may be discharged through the outlet OT in a lower portion through an exhaust path between the shower head 200 and the exhaust unit 100. The outlet OT may be connected to an air blower and may adjust a suction flow rate of the air blower, so a negative pressure in the exhaust unit 100 may be adjusted within a predetermined range.

The gaseous substance may be discharged through the exhaust unit 100, while being prevented from being otherwise discharged externally by the exhaust wings 100W and the adjuster 300. Thus, the substrate processing apparatus 1000 according to an example embodiment may allow a surface of the substrate 10 to be treated without a separate process chamber. Moreover, even when the gap GP between the substrate 10 and the substrate frame 20 exists, a gaseous substance may be prevented from flowing externally. In the substrate processing apparatus 1000 according to an example embodiment, an operation is not performed while the substrate 10 is located in a process chamber. Thus, a configuration of the apparatus may be simplified and miniaturized, and an operation may be effectively performed.

FIGS. 10 through 13 are schematic front views of a substrate processing apparatus according to an example embodiment.

Referring to FIG. 10, a substrate processing apparatus 1000a may include a shower head 200b, a lower surface 200B of which is curved in a different manner from the example embodiment of FIGS. 1A and 1B.

The shower head 200b may include an upper plate 210, a lower plate 220b, and a diffusion plate 225. In the shower head 200b, not only the upper surface 200A but also a lower surface 200B may be curved, and may be curved in the same manner as or in a manner similar to the sagging of the substrate 10.

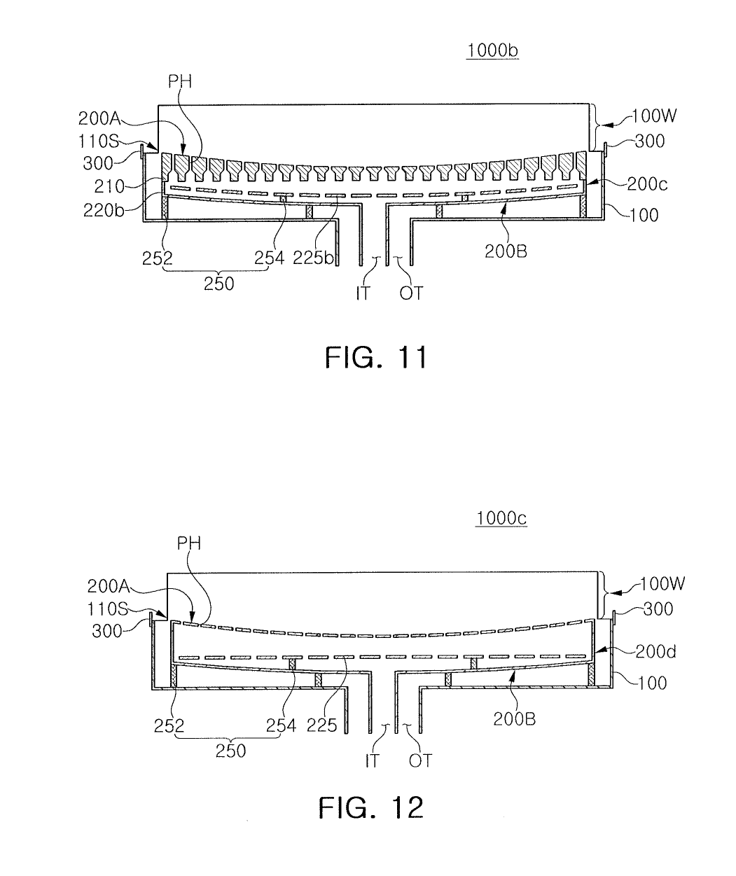

Referring to FIG. 11, a substrate processing apparatus 1000b may include a shower head 200c including a diffusion plate 225b with a curved surface, in a different manner from the example embodiment of FIG. 10.

The diffusion plate 225b may have a curved surface corresponding to the upper surface 200A and the lower surface 200B of the shower head 200c. For example, the diffusion plate 225b may have a curved surface the same as or similar to the upper surface 200A and the lower surface 200B of the shower head 200c.

Referring to FIG. 12, a substrate processing apparatus 1000c may include a shower head 200d having the upper surface 200A in which distribution holes PH are directly formed, in a different manner from the example embodiment of FIG. 10.

In an example embodiment, the distribution holes PH may be not formed by a through tube as illustrated in an example embodiment of FIG. 10, but may be formed in a plate (for example, by machining), forming the upper surface 200A of the shower head 200d. Thus, the upper plate 210 and the lower plate 220 may not be distinguished. The shower head 200d of an example embodiment may be manufactured by, for example, welding, so as to allow a plate in which the distribution holes PH are formed to have a curved surface.

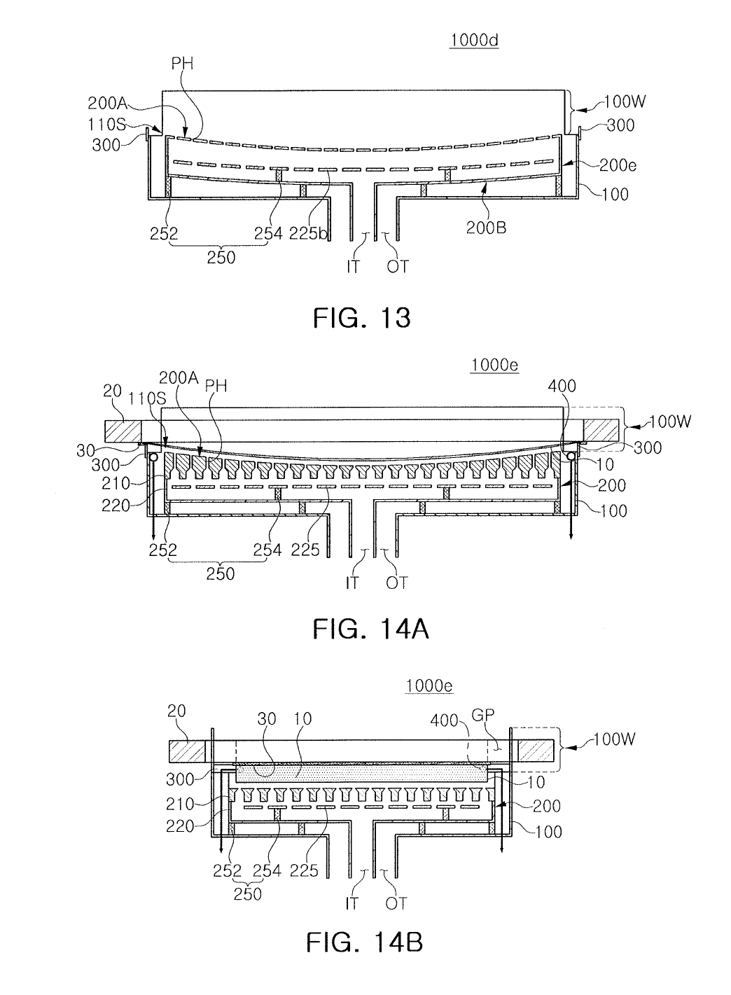

Referring to FIG. 13, a substrate processing apparatus 1000d may include a diffusion plate 225b with a curved surface, as in an example embodiment of FIG. 11, and may include a shower head 200e having the upper surface 200A, in which the distribution holes PH are directly formed, as in an example embodiment of FIG. 12. As described above, according to example embodiments, forms of respective shower heads 200b, 200c, 200d, and 200e may be variously changed, and different components may be combined.

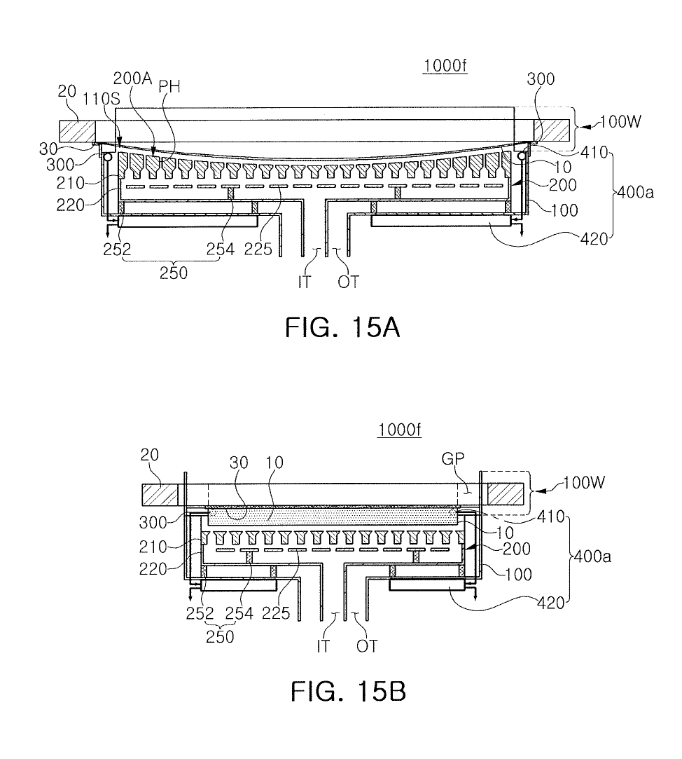

FIGS. 14A through 15B are schematic front views and side views of a substrate processing apparatus according to an example embodiment.

Referring to FIGS. 14A and 14B, a substrate processing apparatus 1000e may further include a sensor 400 measuring a concentration of a process gas at a surface of the substrate 10.

The sensor 400 may be disposed on an upper end of the exhaust unit 100 at an edge of the shower head 200. The sensor 400 may be disposed between the shower head 200 and the exhaust unit 100. The sensor 400 may be fixed to the exhaust unit 100 or the shower head 200. The sensor 400 may be disposed to be close to the substrate 10 so as to measure an actual concentration of the process gas in a surface of the substrate 10, and/or may be disposed in a path through which the process gas is discharged after the substrate 10 is processed. The sensor 400 may include a sensing probe sensing the process gas and a signal processing portion to process information sensed by the sensing probe. In FIGS. 14A and 14B, the sensor 400 is illustrated as a plurality of sensors, but the number of sensors 400 is not limited thereto.

The sensor 400 may measure a concentration of the process gas at a surface of the substrate 10. In addition, as indicated by the arrow, the concentration of the process gas may be transferred to a separate gas control portion, which may analyze information about the concentration having been transmitted, and control an amount of the process gas supplied to the inlet IT, or control a displacement of the process gas exhausted through the outlet OT. Thus, a concentration of the process gas in a surface of the substrate 10 may be kept constant.

Referring to FIGS. 15A and 15B, a substrate processing apparatus 1000f may include a sensor 400a in which a sensing probe 410 and a signal processing portion 420 are separately disposed.

The sensing probe 410 may be disposed on an upper end of the exhaust unit 100 at an edge of the shower head 200. The sensing probe 410 may be disposed between the shower head 200 and the exhaust unit 100. The sensing probe 410 may be fixed to the exhaust unit 100 or the shower head 200. The sensing probe 410 may transmit information having been sensed by sensing the process gas to the signal processing portion 420.

The signal processing portion 420 may be disposed on a lower surface of the exhaust unit 100, that is, on an outer surface of the exhaust unit 100 in a lower portion of the exhaust unit 100. In an example embodiment, the signal processing portion 420 may be disposed on an outer side surface of the exhaust unit 100. The signal processing portion 420 may process information received from the sensing probe 410, and then may transmit the information to a separate gas control portion.

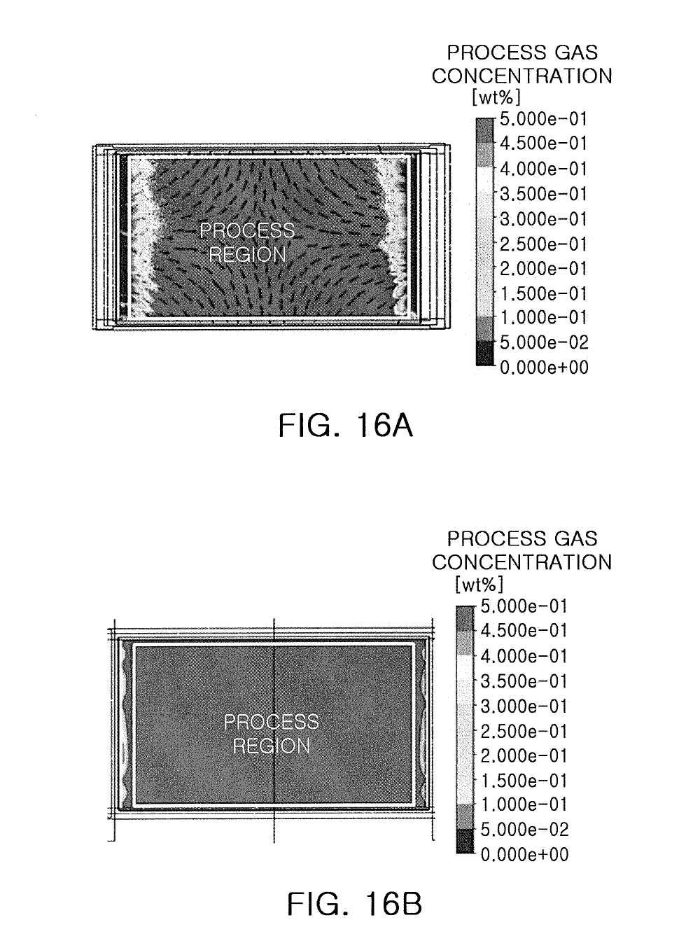

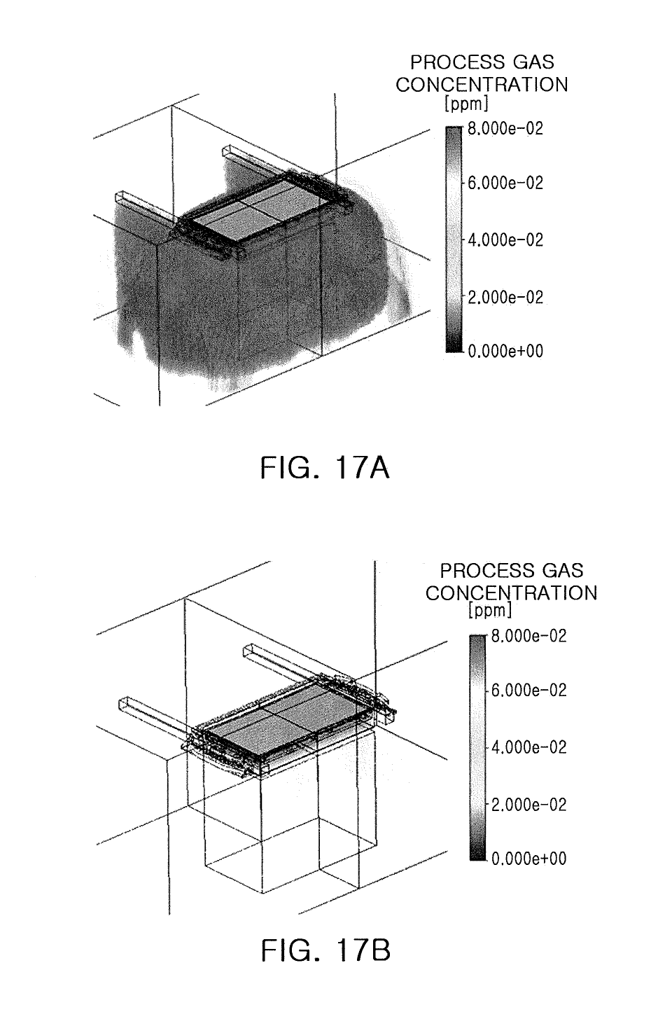

FIGS. 16A through 17B are views illustrating a simulation result of a process gas concentration of a substrate processing apparatus according to an example embodiment.

FIGS. 16A and 16B respectively illustrate a Comparative Example and an Example, in which a concentration of a process gas in a surface of a substrate is compared and illustrated depending on the form of a shower head. In case of the Comparative Example, a substrate processing apparatus is provided while an upper surface of a shower head is flat and a process chamber is not included. In case of the Example, a substrate processing apparatus is provided while an upper surface of a shower head is curved and a process chamber is not included. Simulation was performed under conditions in which a concentration and a flow rate of the process gas were the same and a displacement was also the same.

As illustrated in FIG. 16B, in the case of the Example, in the entirety of a process region of a substrate, a concentration of a gas was about 0.5 wt. % or more. On the other hand, in the case of the Comparative Example illustrated in FIG. 16A, a gas concentration tended to decrease toward an edge of a substrate in a lengthwise direction. In the case of the Example, a shower head having a curved upper surface is included, such that a surface of the substrate is able to be uniformly treated in the entirety of the process region.

FIGS. 17A and 17B respectively illustrate the Comparative Example and the Example, in which a degree of leakage of a process gas is compared and illustrated depending on a structure of an exhaust unit and the presence or absence of an adjuster. In the case of the Comparative Example, a substrate processing apparatus was provided while an exhaust unit without exhaust wings was included and an adjuster was not included. In the case of the Example, a substrate processing apparatus was provided while an exhaust unit having exhaust wings was included and an adjuster was included. Simulation was performed under the conditions in which a concentration and a flow rate of the process gas were the same and a displacement was also the same.

As illustrated in FIG. 17A, in the case of the Comparative Example, the result that a process gas of 0.08 ppm or more is leaked to an exterior of a substrate frame is illustrated. On the other hand, in the case of the Example illustrated in FIG. 17B, a concentration of a process gas leaked to an exterior of a substrate frame is maintained at 0.08 ppm or less, particularly, at 0.04 ppm or less. In the case of the Example, an exhaust unit having exhaust wings and an adjuster are included. Thus, an exhaust performance is improved, such that leakage of a process gas is significantly reduced.

By way of summation and review, when a large substrate is processed, an apparatus capable of increasing the density of equipment while enabling uniform processing of the substrate is desirable.

As set forth above, according to an example embodiment, a device may be formed without a separate process chamber, and a substrate processing apparatus with improved processing capability may be provided.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A substrate processing apparatus, comprising:
an exhaust unit including a lower surface in which an outlet is formed and four side walls extended from the lower surface, the exhaust unit having exhaust wings protruding from two opposing side walls;
a shower head located in the exhaust unit and having distribution holes; and
an adjuster disposed on each of side walls of the exhaust unit between the exhaust wings.

2. The substrate processing apparatus as claimed in claim 1, wherein the exhaust unit is configured to accommodate a substrate having opposite ends thereof fixed to a substrate frame, and
the exhaust wings move to be inserted between opposite ends of the substrate, not fixed to the substrate frame, and the substrate frame.

3. The substrate processing apparatus as claimed in claim 2, wherein the adjuster moves so as to be located adjacent to or to be in contact with the substrate frame.

4. The substrate processing apparatus as claimed in claim 1, further comprising a driving portion lifting the exhaust unit, the shower head, and the adjuster to be close to a surface of a substrate when the substrate is processed.

5. The substrate processing apparatus as claimed in claim 1, wherein the adjuster is fixed to and located on each of side walls not having the exhaust wings.

6. The substrate processing apparatus as claimed in claim 1, wherein the adjuster is provided with a variable length so as to adjust a distance from a substrate.

7. The substrate processing apparatus as claimed in claim 1, wherein the shower head has an upper surface that is curved.

8. The substrate processing apparatus as claimed in claim 7, wherein the exhaust unit is configured to accommodate a substrate having opposite ends thereof fixed to a substrate frame, and
the upper surface of the shower head has a curved surface, corresponding to a curve of the substrate fixed to the substrate frame.

9. The substrate processing apparatus as claimed in claim 7, wherein the shower head has a lower surface that is a curved surface, the curved surface of the lower surface corresponding to curved surface of the upper surface.

10. The substrate processing apparatus as claimed in claim 7, wherein the shower head further includes a diffusion plate disposed in an interior of the shower head, and the diffusion plate has a curved surface corresponding to curved surface of the upper surface.

11. The substrate processing apparatus as claimed in claim 1, further comprising a sensor that includes a sensing probe sensing a substance concentration in a surface of a substrate, and a signal processing portion to process information sensed by the sensing probe, at least a portion of the sensor being located in an upper end of the exhaust unit at an edge of the shower head.

12. The substrate processing apparatus as claimed in claim 11, wherein the sensing probe is located at the upper end of the exhaust unit, and the signal processing portion is located at a lower surface of the exhaust unit.

13. The substrate processing apparatus as claimed in claim 2, wherein:
the shower head allows process gas flowing through an inlet to be provided to a substrate through the distribution holes,
the exhaust unit provides an exhaust path to allow the process gas to be discharged to the outlet, and
the substrate frame and the substrate combine to form a side of a processing cavity, the process gas being supplied to the cavity such that only one side of the substrate is directly exposed to the process gas.

14. The substrate processing apparatus as claimed in claim 1, wherein the exhaust unit processes a substrate while the substrate is accommodated in a region surrounded by the four side walls.

15. The substrate processing apparatus as claimed in claim 1, further comprising a supporting member disposed between a lower surface of the shower head and a lower surface of the exhaust unit.

16. A substrate processing apparatus, comprising:
an exhaust unit including an exhaust path discharging a process material, and having exhaust wings protruding from two opposing side walls;
a shower head located in the exhaust unit and having distribution holes, and having an upper surface that is curved; and
an adjuster disposed on each of side walls of the exhaust unit between the exhaust wings.

17. The substrate processing apparatus as claimed in claim 16, wherein a substrate is provided to the exhaust unit while a portion of the substrate is fixed to a substrate frame, and
the shower head allows process gas to be provided to a surface of the substrate in a lower portion of the substrate.

18. The substrate processing apparatus as claimed in claim 17, wherein the exhaust unit moves to allow the exhaust wings to be inserted between the substrate and the substrate frame in a region in which the substrate and the substrate frame are not fixed to each other, and the adjuster moves so as to be located adjacent to or to be in contact with the substrate frame.

19. The substrate processing apparatus as claimed in claim 17, wherein the upper surface of the shower head has a curved surface, corresponding to the substrate.

20. A substrate processing apparatus, comprising:
an exhaust unit including an exhaust path discharging a process material, and having exhaust wings extended from two opposing side walls and accommodating a substrate therebetween; and
a shower head located in the exhaust unit and having distribution holes.
